(19) United States
(12) Patent Application Publication
(10) Pub. No.: US 2025/0106054 A1
(43) Pub. Date: Mar. 27, 2025

(54) POWER DEVICE AND ETHERNET SYSTEM EMPLOYING DEVICE

(71) Applicant: Nanning FuLian FuGui Precision Industrial Co., Ltd., Nanning (CN)

(72) Inventor: TZYY-GANG WANG, New Taipei (TW)

(21) Appl. No.: 18/372,365

(22) Filed: Sep. 25, 2023

(51) Int. Cl. H04L 12/10; G06F 1/26; H02H 9/04; H03K 17/687

(52) U.S. Cl. CPC H04L 12/10; G06F 1/266; H02H 9/04; H03K 17/6871

(57) ABSTRACT

A powered device (PD) for improving device safety and reliability. The PD comprises a communication interface, a surge protection circuit, a rectifier circuit, a PD chip, a first switch circuit, and a control circuit. The communication interface is configured to transmit data signals and power signals. The surge protection circuit is configured to absorb the peak current in the power signals. The rectifier circuit is configured to convert the power signals into first current signals. The PD chip is configured to communicate with a power sourcing equipment (PSE) according to the data signals. The control circuit is configured to control the first switch circuit to turn on when the PD chip communicates with the PSE successfully, and control the first switch circuit to turn off when a voltage value of the first current signal is less than a first preset voltage value. An Ethernet system is also provided.

### TECHNICAL FIELD

The subject matter herein generally relates to power protection of Ethernet system.

### BACKGROUND

The current electronic equipment (such as computers, mobile phones, outdoor wireless base stations, etc.) has more and more functions, requiring higher power to meet operation needs. Therefore, the lightning strike standard of the electronic equipment is getting higher and higher.

The lightning protection of the electronic equipment usually comprises a lightning surge protection circuit, a rectifier, and a charging chip, which are arranged in a primary side of a transformer. Among them, the lightning surge protection circuit provides the main lightning protection. The common mode lightning current can flow through the rectifier, the charging chip and a capacitor to the ground wire, and the common mode lightning current is related to the value of the capacitor and the lightning voltage. Most of the current rectifiers are discrete Field Effect Transistor or active bridge, which have low current resistance and are easy to be pierced when suffering large lightning strikes (above 4 kV). The field effect transistor inside the charging chip also has low current resistance and can be broken down easily by lightning.

### BRIEF DESCRIPTION OF THE DRAWINGS

Implementations of the present technology will now be described, by way of example only, with reference to the attached figures.

FIG. 1 is a structure diagram of a power device in one embodiment of the present application.

FIG. 2 is a structure diagram of a first switch circuit according to an embodiment of the present disclosure.

FIG. 3 is a structural diagram of a surge protection circuit according to an embodiment of the present disclosure.

FIG. 4 is a structural diagram of the surge protection circuit according to another embodiment of the present disclosure.

FIG. 5 is a structural diagram of a rectifier circuit according to an embodiment of the present disclosure.

FIG. 6 is a structural diagram of an Ethernet system according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. It should be noted that references to “an” or “one” embodiment in this disclosure are not necessarily to the same embodiment, and such references mean “at least one”.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

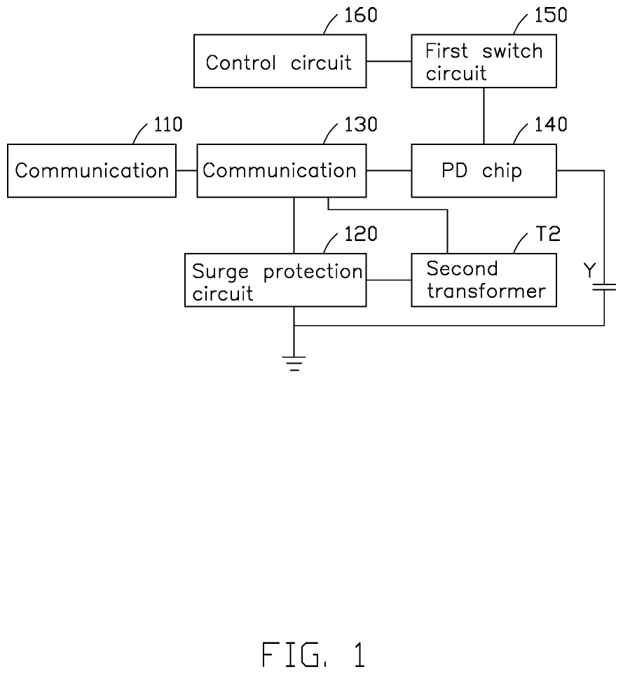

FIG. 1 is a structure diagram of a powered device (PD) 100 in one embodiment of the present application. The PD 100 comprises a communication interface 110, a surge protection circuit 120, a rectifier circuit 130, a PD chip 140, a first switch circuit 150, and a control circuit 160.

The communication interface 110 is configured to transmit data signals and power signals. The surge protection circuit 120 is electrically connected with the communication interface 110 and is configured to absorb a peak current comprised in the power signals. An input end of the rectifier circuit 130 is electrically connected with the communication interface 110. The rectifier circuit 130 is configured to convert the power signals into first current signals. The PD chip 140 is electrically connected with an output end of the rectifier circuit 130 and the communication interface 110. The PD chip 140 is configured to communicate with a power sourcing equipment 200 according to the data signals. The first switch circuit 150 is connected with the PD chip 140 in parallel. The control circuit 160 is electrically connected with the first switch circuit 150. The control circuit 160 is configured to control the first switch circuit 150 to turn on when the PD chip 140 communicates with a power sourcing equipment (PSE) 200 successfully, and control the first switch circuit 150 to turn off when a voltage value of the first current signals is less than a first preset voltage value.

The communication interface 110 can be an Ethernet interface or a local area network (LAN) interface. The communication interface 110 is configured for electrically connecting with the PSE 200 to transmit data signals and power signals. The PD chip 140 communicates with the power supply device 200 by transmitting data signals through the communication interface 110 to complete a handshake communication. The power signals are inputted to the rectifier circuit 130 through the communication interface 110, and the rectifier circuit 130 converts the power signals into the first current signal and outputs the first current signal to the PD chip 140, the control circuit 160, and other functional circuits. If the voltage value of the power signals is greater than a second preset voltage value, the surge protection circuit 120 can be switched on instantaneously, and the surge current can be transmitted to the ground wire to protect the rectifier circuit 130, the PD chip 140, the control circuit 160, and other functional circuits from lightning damage.

When a lightning strike occurs, part of the lightning strike common mode current is absorbed by the surge protection circuit 120, and part of the lightning strike common mode current flows into the rectifier circuit 130. The common mode current flowing into the rectifier circuit 130 can further flow through the PD chip 140 to the ground wire, causing small current devices such as transistors inside the PD chip 140 to be burned.

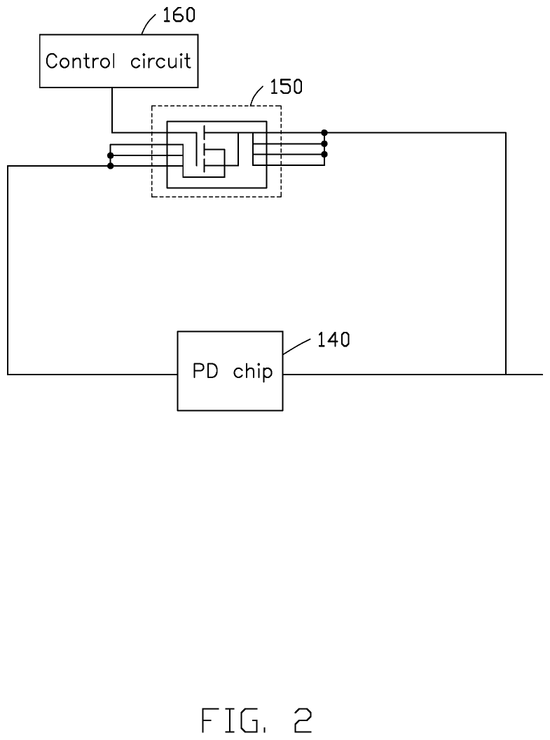

Referring to FIG. 2, the first switch circuit 150 is electrically connected with the PD chip 140 in parallel. Before the PD chip 140 completes communication negotiation with the PSE 200 (communication negotiation based on a handshake protocol), the control circuit 160 controls the first switch circuit 150 to turn off. After the PD chip 140 completes the communication negotiation with the PSE 200, the control circuit 160 controls the first switch circuit 150 to turn on. At this time, if the current of the communication interface 110 is too large, the common mode surge current can flow through the rectifier circuit 130 and the first switch circuit 150, and will not flow into the PD chip 140. The PD chip 140 can be prevented from being damaged by large current. When the power supply voltage of the PD chip 140 is less than the minimum operating voltage (for example the PD 100 is power off), the control circuit 160 controls the first switch circuit 150 to turn off, to reduce the circuit loss. Among them, the control circuit 160 can determine whether the PD chip 140 completes the communication negotiation with the PSE 200 by directly obtaining the data signals of the communication interface 110, or the PD chip 140 can output notification information to the control circuit 160 after completing the communication negotiation with the PSE 200, and the control circuit 160 can respond to the notification information and control the first switch circuit 150 to turn on. The control circuit 160 can be completed by a microprocessor, a field programmable gate array (FPGA) or other chips. The first switch circuit 150 can be a transistor, such as a P-channel Metal Oxide Semiconductor (PMOS) tube, a N-channel Metal Oxide Semiconductor (NMOS) tube, etc. For example, the first switch circuit 150 comprises a third Metal Oxide Semiconductor (MOS) tube Q3. A drain and a source of the third MOS transistor Q3 are electrically connected to the PD chip 140, and a gate of the third MOS transistor Q3 is electrically connected to the control circuit 160.

The rectifier circuit 130 can rectify the input power signals and output rectified power signals to the PD chip 140, so that the PD chip 140 can work normally. By connecting the first switch circuit 150 in parallel to the PD chip 140, the common mode surge current caused by lightning strikes can pass through the first switch circuit 150, the PD chip 140 can be avoided to be damaged by large current, and the safety and reliability of the PD 100 can be improved.

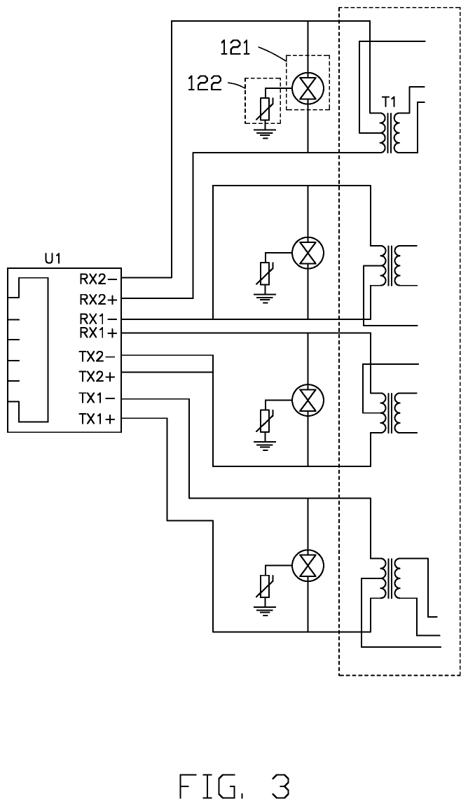

FIG. 3 is a structural diagram of the surge protection circuit 120 according to an embodiment of the present disclosure.

In one embodiment, the communication interface 100 comprises a first chip U1 and a first transformer T1. The first chip U1 is electrically connected with a primary side of the first transformer T1. The first chip U1 is configured to transmit the data signals and the power signals. The surge protection circuit 120 comprises a first protector 121 and a second protector 122. The first protector 121 is connected with a primary side of the first transformer T1 in parallel. The first protector 121 is turned on when a voltage value of the power signals is greater than a second preset voltage value. A first end of the second protector 122 is electrically connected with the first protector 121, and a second end of the second protector 122 is grounded. The second protector 122 is turned on when the voltage value of the power signals is greater than the second preset voltage value.

The first protector 121 is connected with the primary side of the first transformer T1 in parallel. That is, the first protector 121 is connected with the corresponding two pins on the first chip U1. For example, the primary side of the first transformer T1 is connected with the TX1 pin and the RX1 pin of the first chip U1, and the first protector 121 is connected with the primary side of the first transformer T1 in parallel. That is, the first protector 121 is connected with the TX1 pin and the RX1 pin of the first chip U1 in parallel. When the lightning strike occurs, the first protector 121 is turned on, and the primary side of the first transformer T1 and the TX1 pin and the RX1 pin of the first chip U1 can be shorted out, so that the large current flows from the first protector 121 and the second protector 122 into the ground wire to avoid the first chip U1, the first transformer T1, and other circuits to be damaged by the large current. The first protector 121 can be a gas discharge tube. The second protector 122 can be a metal oxide varistor, a bidirectional transient overvoltage protector, or a transient diode.

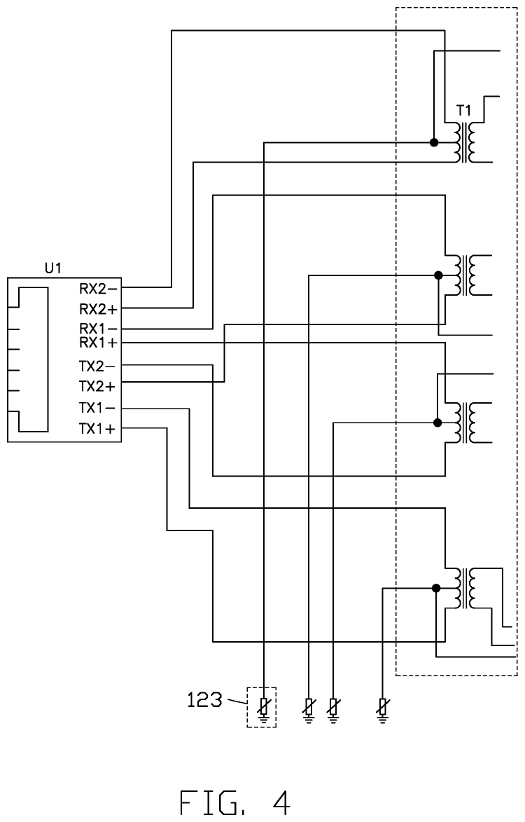

FIG. 4 is a structural diagram of the surge protection circuit 120 according to another embodiment of the present disclosure.

In one embodiment, the communication interface 110 can comprise a first chip U1 and a first transformer T1, the first chip U1 is electrically connected with a primary side of the first transformer T1, the first chip U1 is configured to transmit the data signals and the power signals. The surge protection circuit 120 can comprise a third protector 123. A first end of the third protector 123 is connected with a center tap of the primary side of the first transformer T1, and the second end of the third protector 123 is grounded. The third protector 123 is turned on when a voltage value of the power signals is greater than a second preset voltage value.

When the lightning strike occurs, the third protector 123 is switched on instantaneously to send the large current into the ground wire to prevent the first transformer T1 and other circuits from being damaged by the large current. The surge protection can be realized through the third protector 123, with simple mechanism and the number of protectors used is smaller. The third protector 123 can be a metal oxide varistor, a bidirectional transient overvoltage protector, or a transient diode.

In one embodiment, the number of the first transformer T1 is multiple, and the number of the first protector 121 and the number of the second protector 122 are respectively consistent with the number of the first transformer T1. In this way, the plurality of first transformers T1 and the plurality of pins of the first chip U1 can be protected.

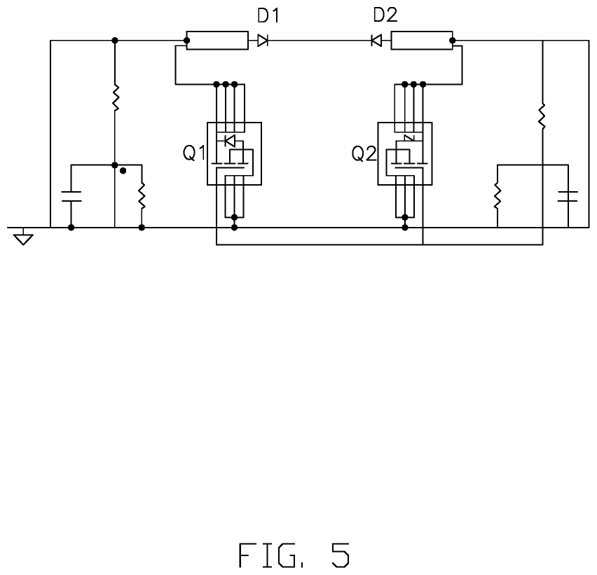

FIG. 5 is a structural diagram of a rectifier circuit according to an embodiment of the present disclosure.

In one embodiment, the rectifier circuit 130 comprises a first diode D1, a second diode D2, a first MOS transistor Q1, and a second MOS transistor Q2. A first end of the first diode DI is electrically connected with a first end of the first MOS transistor Q1 to form a first input end of the rectifier circuit 130. A second end of the first diode D1 is electrically connected with a first end of the second diode D2 to form a first output end of the rectifier circuit 130. A second end of the second diode D2 is electrically connected with a first end of the second MOS transistor Q2 to form a second input end of the rectifier circuit 130, and a second end of the first MOS transistor Q1 is electrically connected with a second end of the second MOS transistor Q2 to form a second output end of the rectifier circuit 130.

In a case of large current/voltage fluctuations (such as lightning strikes), the surge protection circuit 120 can cause the voltage of the communication interface 110 to change instantaneously (the surge voltage can be below 90V, but sometimes drop to 0V). The existing full-bridge rectifier is composed of field effect transistors, which can transmit a voltage fluctuation to the PD chip 140, causing the PD chip 140 to misoperate and damaged. The rectifier circuit 130 of this embodiment utilizes the single conduction characteristics of the first diode D1 and the second diode D2 to prevent voltage fluctuations from being transmitted to the PD chip 140, when the voltage of the communication interface 110 changes instantaneously, the PD chip 140 can be prevented from being affected by voltage fluctuations. Among them, the number of rectifier circuit 130 can be multiple.

In one embodiment, the PD 100 may further comprise a second transformer T2. A primary side of the second transformer T2 is electrically connected with an output end of the rectifier circuit 130. The second transformer T2 is configured to transmit the first current signals.

The first current signals output by the rectifier circuit 130 can be transmitted to the rear circuit of the PD 100 through the second transformer T2, which has the function of boost/reduce voltage and safety isolation. When the primary side or the secondary side of the second transformer T2 is abnormal, the other side will not be affected.

In one embodiment, the PD 100 further comprises a first capacitor Y. A first end of the first capacitor Y is electrically connected with the PD chip 140, and a second end of the first capacitor Y is grounded. The magnitude of the lightning strike common mode current is related to the capacitance of the first capacitor Y and the lightning strike voltage. The lightning common mode current can be limited to a suitable range by selecting a suitable capacitance value to avoid the circuits being damaged by large current.

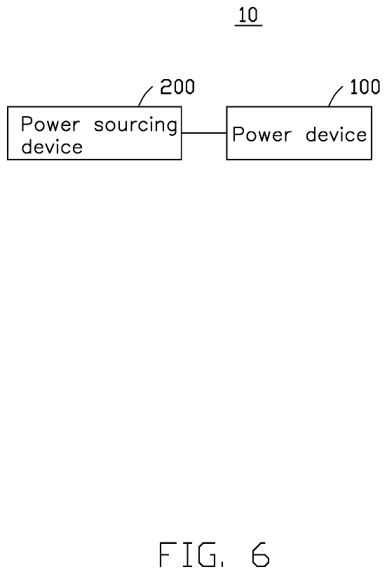

FIG. 6 is a structural diagram of an Ethernet system 10 according to an embodiment of the present disclosure.

The Ethernet system 10 comprises the PD 100 and the PSE 200. The detailed structure of the PD 100 can be referred to the above embodiments. It can be understood that the PD 100 can be used in the Ethernet system 10, the embodiment of the Ethernet system 10 comprises all the technical schemes of all the embodiments of the PD 100, and the technical effects achieved are exactly the same, and will not be repeated here.

The exemplary embodiments shown and described above are only examples. Many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A powered device (PD), comprising a communication interface, a surge protection circuit, a rectifier circuit, a PD chip, a first switch circuit, and a control circuit;
wherein the communication interface is configured to transmit data signals and power signals, the surge protection circuit is electrically connected with the communication interface and is configured to absorb a peak current comprised in the power signals, an input end of the rectifier circuit is electrically connected with the communication interface, the rectifier circuit is configured to convert the power signals into first current signals, the PD chip is electrically connected with an output end of the rectifier circuit and the communication interface, the PD chip is configured to communicate with a power sourcing equipment (PSE) according to the data signals, the first switch circuit is connected with the PD chip in parallel, the control circuit is electrically connected with the first switch circuit, the control circuit is configured to control the first switch circuit to turn on when the PD chip communicates with the PSE successfully, and control the first switch circuit to turn off when a voltage value of the first current signals is less than a first preset voltage value.

2. The PD of claim 1, wherein the communication interface comprises a first chip and a first transformer, the first chip is electrically connected with a primary side of the first transformer, the first chip is configured to transmit the data signals and the power signals,
the surge protection circuit comprises a first protector and a second protector, the first protector is connected with the primary side of the first transformer in parallel, the first protector is turned on when a voltage value of the power signals is greater than a second preset voltage value, a first end of the second protector is electrically connected with the first protector, and a second end of the second protector is grounded, the second protector is turned on when the voltage value of the power signals is greater than the second preset voltage value.

3. The PD of claim 1, wherein the communication interface comprises a first chip and a first transformer, the first chip is electrically connected with a primary side of the first transformer, the first chip is configured to transmit the data signals and the power signals,
the surge protection circuit comprises a third protector, a first end of the third protector is connected with a center tap of the primary side of the first transformer, and the second end of the third protector is grounded, the third protector is turned on when a voltage value of the power signals is greater than a second preset voltage value.

4. The PD of claim 2, wherein the first protector is a gas discharge tube, the second protector is selected from a group consisting of a metal oxide varistor, a bidirectional transient overvoltage protector, and a transient diode.

5. The PD of claim 2, wherein the number of the first transformer is multiple, and the number of the first protector and the number of the second protector are respectively consistent with the number of the first transformer.

6. The PD of claim 1, wherein the rectifier circuit comprises a first diode, a second diode, a first metal oxide semiconductor (MOS) transistor, and a second MOS transistor, a first end of the first diode is electrically connected with a first end of the first MOS transistor to form a first input end of the rectifier circuit, a second end of the first diode is electrically connected with a first end of the second diode to form a first output end of the rectifier circuit, a second end of the second diode is electrically connected with a first end of the second MOS transistor to form a second input end of the rectifier circuit, and a second end of the first MOS transistor is electrically connected with a second end of the second MOS transistor to form a second output end of the rectifier circuit.

7. The PD of claim 1, wherein the first switch circuit comprises a third MOS transistor.

8. The PD of claim 1, further comprising a second transformer, wherein a primary side of the second transformer is electrically connected with an output end of the rectifier circuit, the second transformer is configured to transmit the first current signals.

9. The PD of claim 1, further comprising a first capacitor, wherein a first end of the first capacitor is electrically connected with the PD chip, and a second end of the first capacitor is grounded.

10. An Ethernet system comprising a powered device (PD) and a power sourcing equipment (PSE), wherein the PD comprises a communication interface, a surge protection circuit, a rectifier circuit, a PD chip, a first switch circuit, and a control circuit;
the communication interface is configured to transmit data signals and power signals, the surge protection circuit is electrically connected with the communication interface and is configured to absorb the peak current in the power signals, an input end of the rectifier circuit is electrically connected with the communication interface, the rectifier circuit is configured to convert the power signals into first current signals, the PD chip is electrically connected with an output end of the rectifier circuit and the communication interface, the PD chip is configured to communicate with a PSE according to the data signals, the first switch circuit is connected with the PD chip in parallel, the control circuit is electrically connected with the first switch circuit, the control circuit is configured to control the first switch circuit on when the PD chip communicates with the PSE successfully, and to control the first switch circuit off when a voltage value of the first current signal is less than a first preset voltage value.

11. The Ethernet system of claim 10, wherein the communication interface comprises a first chip and a first transformer, the first chip is electrically connected with a primary side of the first transformer, the first chip is configured to transmit the data signals and the power signals,
the surge protection circuit comprises a first protector and a second protector, the first protector is connected with the primary side of the first transformer in parallel, the first protector is turned on when a voltage value of the power signals is greater than a second preset voltage value, a first end of the second protector is electrically connected with the first protector, and a second end of the second protector is grounded, the second protector is turned on when the voltage value of the power signals is greater than the second preset voltage value.

12. The Ethernet system of claim 10, wherein the communication interface comprises a first chip and a first transformer, the first chip is electrically connected with a primary side of the first transformer, the first chip is configured to transmit the data signals and the power signals,
the surge protection circuit comprises a third protector, a first end of the third protector is connected with a center tap of the primary side of the first transformer, and the second end of the third protector is grounded, the third protector is turned on when a voltage value of the power signals is greater than a second preset voltage value.

13. The Ethernet system of claim 11, wherein the first protector is a gas discharge tube, the second protector is selected from a group consisting of a metal oxide varistor, a bidirectional transient overvoltage protector, and a transient diode.

14. The Ethernet system of claim 11, wherein the number of the first transformer is multiple, and the number of the first protector and the number of the second protector are respectively consistent with the number of the first transformer.

15. The Ethernet system of claim 10, wherein the rectifier circuit comprises a first diode, a second diode, a first metal oxide semiconductor (MOS) transistor, and a second MOS transistor, a first end of the first diode is electrically connected with a first end of the first MOS transistor to form a first input end of the rectifier circuit, a second end of the first diode is electrically connected with a first end of the second diode to form a first output end of the rectifier circuit, a second end of the second diode is electrically connected with a first end of the second MOS transistor to form a second input end of the rectifier circuit, and a second end of the first MOS transistor is electrically connected with a second end of the second MOS transistor to form a second output end of the rectifier circuit.

16. The Ethernet system of claim 10, wherein the first switch circuit comprises a third MOS transistor.

17. The Ethernet system of claim 10, wherein the PD further comprises a second transformer, a primary side of the second transformer is electrically connected with an output end of the rectifier circuit, the second transformer is configured to transmit the first current signals.

18. The Ethernet system of claim 10, wherein the PD further comprises a first capacitor, a first end of the first capacitor is electrically connected with the PD chip, and a second end of the first capacitor is grounded.
